(19) United States
(12) Patent Application Publication
(10) Pub. No.: US 2013/0340636 A1
(43) Pub. Date: Dec. 26, 2013

(54) A KIND OF TINPLATE CYLINDRICAL CAN SCREEN PROCESS PRINTING TECHNOLOGY

(71) Applicant: DONGGUAN RENAULTIN METAL PRODUCTS CO., LTD, (US)

(72) Inventor: Hongzhong LIN, Dongguan City (CN)

(73) Assignee: DONGGUAN RENAULTIN METAL PRODUCTS CO., LTD, Dongguan City (CN)

(21) Appl. No.: 13/764,293

(22) Filed: Feb. 11, 2013

(30) Foreign Application Priority Data
Jun. 20, 2012 (CN) 201210204495.0

(51) Int. Cl. G03F 7/12

(52) U.S. Cl. CPC G03F 7/12
USPC 101/116

(57) ABSTRACT

This invention belongs to the screen process printing field, disclosing the tinplate cylindrical can screen printing technology, that is, prepare the screen first and then carry out the screen printing with pneumatic cylindrical screen printer of high accuracy; The said screen workpieces' periphery are elongated by 3 mm and the said 3 mm range are respectively made into gradient screentone of 50%, 35% and 15% at the screen trail, being the connection for the screen printing. The said screen is coated with UV curable varnish, which is mainly made from the following components based on the weight proportion: acrylic mixed resin, 70%; acrylic mixed monomer, 20%, mixed photosensitizer, 4%-8%; and organic siloxane, the adjuvant, 2%-6%. The room temperature for blending UV curable varnish ranges from 23° C. to 33° C. The purpose of this invention is to provide a technology with high transparency, smooth workpiece surface and free of any added textures.

### TECHNICAL FIELD OF THE INVENTION

This invention involves the screen process printing field, especially a kind of tinplate cylindrical can screen process printing technology.

### BACKGROUND OF THE INVENTION

The existing tinplate cylindrical can UV gluing technology is mainly to use more than two rubber rollers for coating, with the following defects: 1. Large usage amount of UV inks; 2. Lower transparency, below 85%; 3. Textures will occur on the working surfaces coated with rubber rollers.

### CONTENT OF INVENTION

For solving the said technical problems, the purpose of this invention is to provide a kind of ink-saving tinplate cylindrical can screen process printing technology with high transparency, smooth workpiece surface and free of any added textures.

The complete technical scheme of this invention is a kind of tinplate cylindrical can screen process printing technology, which is characterized in that prepare the screen first and then carry out the screen printing with pneumatic cylindrical screen printer of high accuracy; The said screen workpieces' periphery are elongated by 3 mm and the said 3 mm range are respectively made into gradient screentone of 50%, 35% and 15% at the screen trail, being the connection for the screen printing. The said screen is coated with UV curable varnish, which is mainly made from the following components based on the weight proportion: acrylic mixed resin, 70%; acrylic mixed monomer (C15H20O6, C1H2406, C12H1804), 20%, mixed photosensitizer (C10H12O2, C13H10O), 4%-8%; and organic siloxane, the adjuvant, 2%-6%.

The said room temperature for blending UV curable varnish ranges from 23° C. to 33° C.

The said content of mixed photosensitizer fluctuates with the air dryness and the room temperature, that is, the higher the air dryness, the less the mixed photosensitizer to be added, on the contrary, the wetter the air, the more the mixed photosensitizer.

The said usage amount of organic siloxane varies with the smoothness of working surfaces, that is, the rougher the working surface, the less the organic siloxane to be added, on the contrary, the smoother the working surface, the more the organic siloxane.

The parts of working surfaces required to be processed with UV screen printing should be washed or coated with CH3COO2H5 before being oiled.

The reserved amount of the said curable varnish on the screen at each time ranges from 10 g to 50 g.

The said fixture used in the screen preparation should be made into a kind of semi-automatic mold possessed of umbrella principle, and the stroke of the said fixture is 8 mm.

In a word, compared with the existing techniques, this invention has the following advantages:

This invention adopts the screen process printing technology, coating the UV curable varnish on the surfaces of tinplate cylindrical cans, and the usage amount of UV curable varnish depends on the requirements of workpieces, being 0.0025 mm to the thinnest with the transparency above 93% and the working surface after being processed with UV screen printing is smooth without any added textures.

### SPECIFIC IMPLEMENTING METHODS

The following specific embodiments are used for introducing this invention in detail, and the schematic embodiments of this invention and descriptions for explaining this invention are not used for defining this invention.

### Embodiment 1:

This embodiment is a kind of tinplate cylindrical can screen process printing technology which is characterized in that prepare the screen first and then carry out the screen printing with pneumatic cylindrical screen printer of high accuracy; The said screen workpieces' periphery are elongated by 3 mm and the said 3 mm range are respectively made into gradient screentone of 50%, 35% and 15% at the screen trail, being the connection for the screen printing. The said fixture used in the screen preparation should be made into a kind of semi-automatic mold possessed of umbrella principle, and the stroke of the said fixture is 8 mm. The said screen is coated with UV curable varnish, which is mainly made from the following components based on the weight proportion: acrylic mixed resin, 70%; acrylic mixed monomer (C15H20O6, C1H2406, C12H1804), 20%; mixed photo sensitizer (C10H12O2, C13H10O), 4%-8%; and organic siloxane, the adjuvant, 2%-6%. The room temperature for blending UV curable varnish ranges from 23° C. to 33° C. The said content of mixed photosensitizer fluctuates with the air dryness and the room temperature, that is, the higher the air dryness, the less the mixed photosensitizer to be added, on the contrary, the wetter the air, the more the mixed photosensitizer. The said usage amount of organic siloxane varies with the smoothness of working surfaces, that is, the rougher the working surface, the less the organic siloxane to be added, on the contrary, the smoother the working surface, the more the organic siloxane. The parts of working surfaces required to be processed with UV screen printing should be washed or coated with CH3COO2H5 before being oiled. The reserved amount of the said curable varnish on the screen at each time ranges from 10 g to 50 g, and if less than 10 g, the surfaces of workpieces after being processed with UV curable varnish will become slightly rough.

In a word, this invention adapts the screen process printing technology, coating the UV curable varnish on the surfaces of tinplate cylindrical cans, and the usage amount of UV curable varnish depends on the requirements of workpieces, being 0.0025 mm to the thinnest with the transparency above 93% and the working surface after being processed with UV screen printing is smooth without any added textures.

The statement above introduces the technical scheme provided by the embodiment of this invention in detail. In this article, specific examples are used for elaborating the principle and implementation methods of the embodiment of this invention, and the description of embodiment above is just used for assisting to understand the principle of embodiment of this invention. In addition, the common technical personnel in this field will make some changes in the specific implementation methods and in the application scope based on the embodiment of this invention. In a word, the content of this introduction should not be deemed as the definition of this invention.

1. A kind of tinplate cylindrical can screen process printing technology, which is characterized in that prepare the screen first and then carry out the screen printing with pneumatic cylindrical screen printer of high accuracy; The said screen workpieces' periphery are elongated by 3 mm and the said 3 mm range are respectively made into gradient screentone of 50%, 35% and 15% at the screen trail, being the connection for the screen printing. The said screen is coated with UV curable varnish, which is mainly made from the following components based on the weight proportion: acrylic mixed resin, 70%; acrylic mixed monomer (C15H20O6, C1H2406, C12H1804), 20%, mixed photosensitizer (C10H12O2, C13H10O), 4%-8%; and
organic siloxane, the adjuvant, 2%-6%.

2. The tinplate cylindrical can screen process printing technology, as set forth in claim 1, is characterized in that the room temperature for blending UV curable varnish ranges from 23° C. to 33° C.

3. The tinplate cylindrical can screen process printing technology, as set forth in claim 1, is characterized in that the content of mixed photosensitizer fluctuates with the air dryness and the room temperature, that is, the higher the air dryness, the less the mixed photosensitizer to be added, on the contrary, the wetter the air, the more the mixed photosensitizer.

4. The tinplate cylindrical can screen process printing technology, as set forth in claim 1, is characterized in that the said usage amount of organic siloxane varies with the smoothness of working surfaces, that is, the rougher the working surface, the less the organic siloxane to be added, on the contrary, the smoother the working surface, the more the organic siloxane.

5. The tinplate cylindrical can screen process printing technology, as set forth in claim 1, is characterized in that the parts of working surfaces required to be processed with UV screen printing should be washed or coated with CH3COO2H5 before being oiled.

6. The tinplate cylindrical can screen process printing technology, as set forth in claim 1, is characterized in that the reserved amount of the said curable varnish on the screen at each time ranges from 10 g to 50 g.

7. The tinplate cylindrical can screen process printing technology, as set forth in claim 1, is characterized in that the said fixture used in the screen preparation should be made into a kind of semi-automatic mold possessed of umbrella principle, and the stroke of the said fixture is 8 mm.
